(19) United States
(12) Patent Application Publication
(10) Pub. No.: US 2012/0026687 A1
(43) Pub. Date: Feb. 2, 2012

(54) HOUSING AND ELECTRONIC DEVICE USING THE SAME

(75) Inventor: YOU-XI WEN, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 12/964,023

(22) Filed: Dec. 9, 2010

(30) Foreign Application Priority Data
Jul. 29, 2010 (CN) 201010240084.8

(51) Int. Cl. H05K 7/20

(52) U.S. Cl. 361/692

(57) ABSTRACT

A housing of an electronic device includes a sidewall and a heat dissipating zone on the sidewall. The heat dissipating zone includes a reinforcement portion on the sidewall. The reinforcement portion defines heat dissipating holes. The reinforcement portion can extend inwardly from the sidewall of the housing or outwardly from the sidewall of the housing. Each heat dissipating hole has a width equal to or less than 3.5 millimeters.

### BACKGROUND

1. Technical Field

The present disclosure relates generally to device housings, and especially to a housing with heat dissipating holes and an electronic device using the same.

2. Description of Related Art

A commonly used electronic device generally includes a housing defining a plurality of heat dissipating holes on a side surface thereof. However, a size of the heat dissipating holes is often very small to reduce electromagnetic radiation, such that the heat dissipating ability of the housing is limited accordingly.

Therefore, there is room for improvement within the art.

### BRIEF DESCRIPTION OF THE DRAWINGS

The components in the drawings are not necessarily drawn to scale, the emphasis instead being placed upon clearly illustrating the principles of the present disclosure. Moreover, in the drawings, like reference numerals designate corresponding parts throughout the views.

FIG. 1 is an isometric view of a first embodiment of an electronic device.

FIG. 2 is an enlarged view of a circled portion II shown in FIG. 1.

FIG. 3 is an isometric view of a second embodiment of an electronic device.

FIG. 4 is an enlarged view of a circled portion IV shown in FIG. 3.

### DETAILED DESCRIPTION

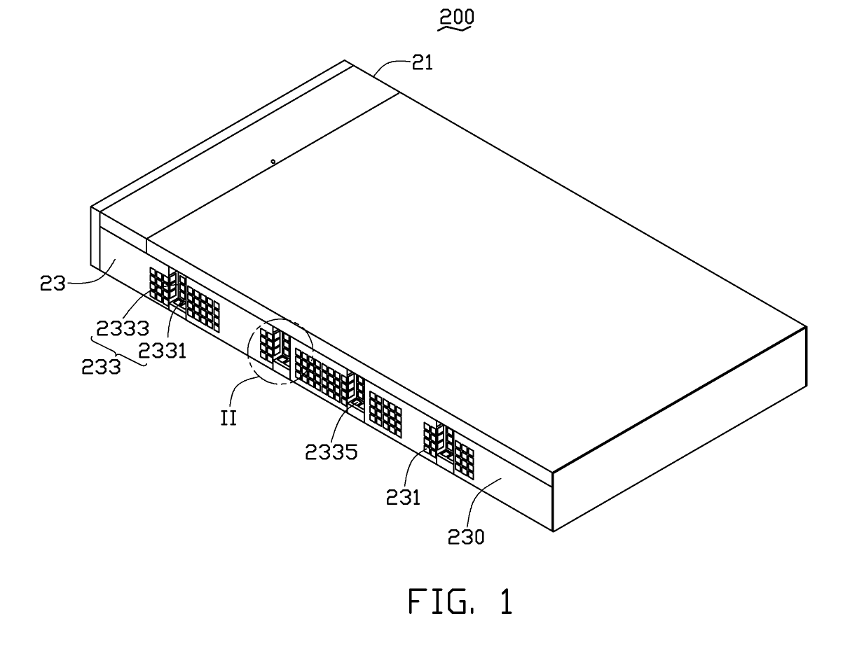

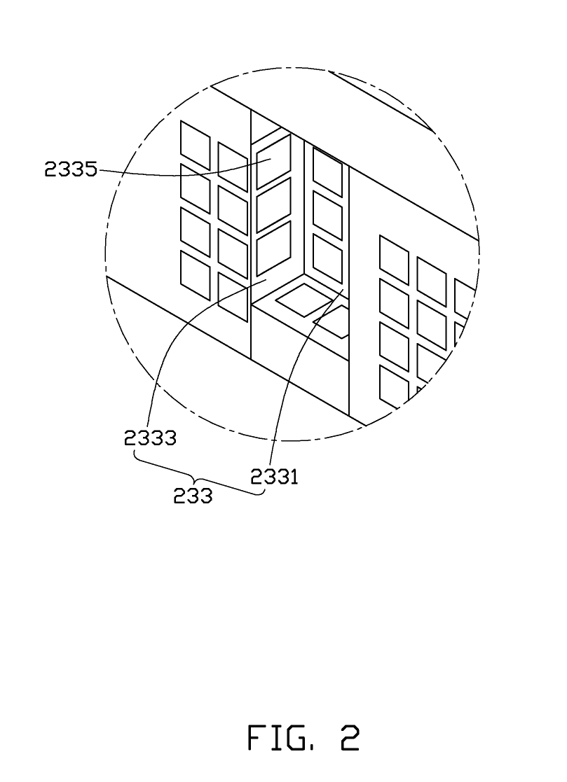

Referring to FIGS. 1 and 2, a first embodiment of the electronic device 200 includes a housing 23. The housing 23 includes a heat dissipating zone 231 thereon. In the illustrated embodiment, the housing 23 is rectangular, and the heat dissipating zone 231 is formed at a sidewall 230 of the housing 23. The heat dissipating zone 231 includes a rectangular reinforcement portion 233 curving inwardly on the sidewall 230 of the housing 23 to prevent impact with nearby objects. The reinforcement portion 233 includes a first heat dissipating wall 2331 substantially parallel with the sidewall 230 and four second heat dissipating walls 2333 extending from four edges of the first heat dissipating wall 2331 to the sidewall 230. The heat dissipating zone 231 defines a plurality of heat dissipating holes 2335 at the first and second heat dissipating walls 2331, 2333 of the reinforcement portion 233 and the other portion of the heat dissipating zone 231. A minimal width of the heat dissipating hole 2335 is 3.5 mm (millimeters) or less to reduce electromagnetic radiation from the electronic device 200. Alternatively, the reinforcement portion 233 may be cylindrical, semi-columnar, frustum of a pyramid, or other, and the number of second heat dissipating walls 2333 may be one, two, three, five or more accordingly.

The reinforcement portion curving on the sidewall 230 of the housing 23 increases an area of the heat dissipating zone 233, thus the number of heat dissipating holes 2335 may be increased, and the heat dissipating ability of the housing 23 can be improved accordingly. The housing 23 and the reinforcement portion 233 may be manufactured by stamping. The shape and number of the heat dissipating holes 2335 may be varied as desired.

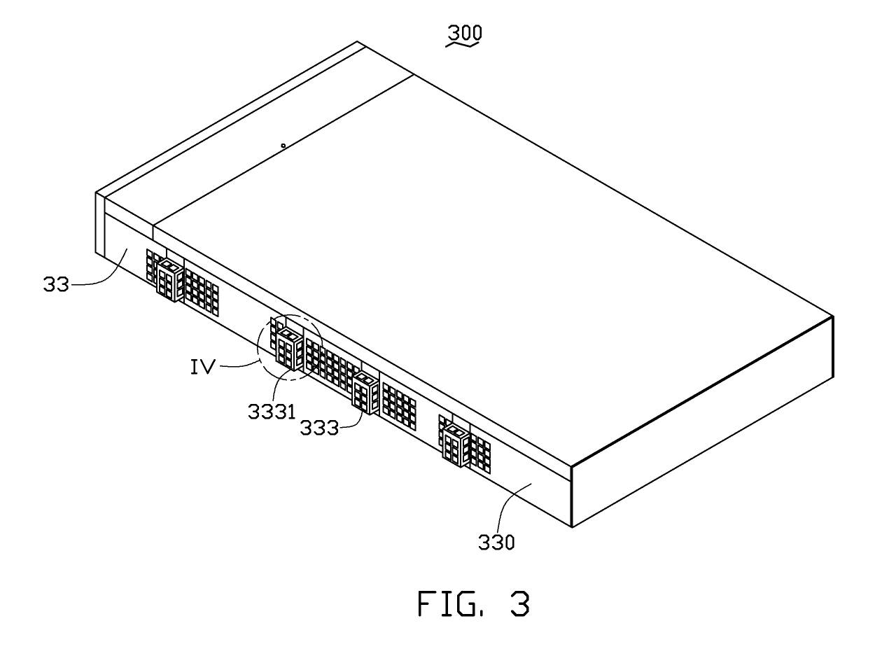

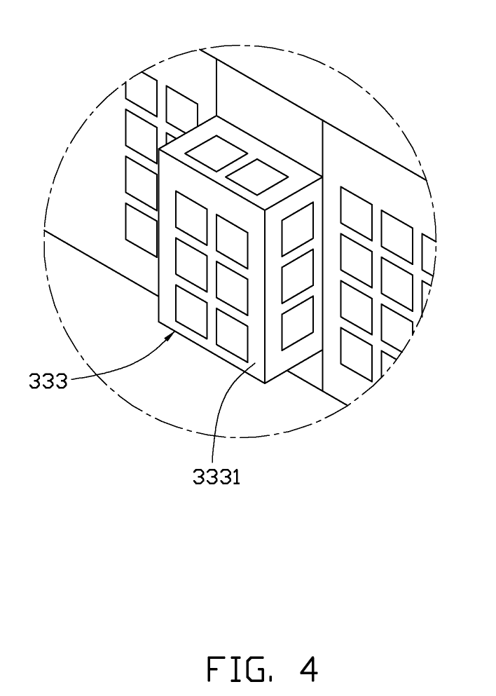

Referring to FIGS. 3 and 4, a second embodiment of the electronic device 300 differs from the first electronic device 200 only in that the reinforcement portion 333 extends outwardly from the sidewall 330 of a housing 33 to conserve space within the electronic device 300. Thus, heat dissipating walls 3331 of the reinforcement portion 333 extend outwardly.

It is believed that the present embodiments and their advantages will be understood from the foregoing description, and it will be apparent that various changes may be made thereto without departing from the spirit and scope of the disclosure or sacrificing all of its material advantages.

What is claimed is:

1. A housing of an electronic device comprising:
a sidewall and a heat dissipating zone on the sidewall, wherein the heat dissipating zone comprises a reinforcement portion extending from the sidewall, and the reinforcement portion defines a plurality of heat dissipating holes.

2. The housing of claim 1, wherein each heat dissipating hole has a width equal to or less than 3.5 millimeters.

3. The housing of claim 1, wherein the reinforcement portion extends outwardly on the sidewall.

4. The housing of claim 1, wherein the reinforcement portion extends inwardly on the sidewall.

5. The housing of claim 4, wherein the reinforcement portion comprises a first heat dissipating wall substantially parallel with the sidewall and at least a second heat dissipating wall interconnecting the sidewall and the first heat dissipating wall.

6. The housing of claim 5, wherein the second heat dissipating wall is substantially perpendicular to the first heat dissipating wall.

7. The housing of claim 6, wherein the reinforcement portion is substantially rectangular.

8. The housing of claim 5, wherein a number of the second heat dissipating walls is four.

9. A electronic device comprising:
a housing comprising a sidewall and a heat dissipating zone on the sidewall, the heat dissipating zone comprising a reinforcement portion on the sidewall, and the reinforcement portion defining a plurality of heat dissipating holes.

10. The electronic device of claim 9, wherein each heat dissipating hole has a width equal to or less than 3.5 millimeters.

11. The electronic device of claim 9, wherein the reinforcement portion is extending outwardly on the sidewall.

12. The housing of claim 9, wherein the reinforcement portion is extending inwardly on the sidewall.

13. The electronic device of claim 12, wherein the reinforcement portion comprises a first heat dissipating wall substantially parallel with the sidewall and at least a second heat dissipating wall interconnecting the sidewall and the first heat dissipating wall.

14. The electronic device of claim 13, wherein the second heat dissipating wall is substantially perpendicular to the first heat dissipating wall.

15. The electronic device of claim 14, wherein the reinforcement portion is substantially rectangular.

16. The electronic device of claim 13, wherein a number of the second heat dissipating walls is four.
